(19) United States
(12) Patent Application Publication
(10) Pub. No.: US 2015/0321214 A1
(43) Pub. Date: Nov. 12, 2015

(54) APPARATUSES AND SYSTEMS FOR SELECTIVELY APPLYING A PROTECTIVE COATING TO ELECTRONIC COMPONENTS AND METHODS RELATED THERETO

(71) Applicant: HZO, Inc., Draper, UT (US)

(72) Inventors: Dana Cox, American Fork, UT (US); Max Sorenson, Herriman, UT (US)

(21) Appl. No.: 14/794,713

(22) Filed: Jul. 8, 2015

Related U.S. Application Data
(63) Continuation of application No. PCT/US14/10739, filed on Jan. 8, 2014.
(60) Provisional application No. 61/750,342, filed on Jan. 8, 2013.

(51) Int. Cl. B05C 21/00; B05C 13/00; C23C 16/458; C23C 14/50; C23C 16/04; B05D 5/08; C23C 14/04

(52) U.S. Cl. CPC B05C 21/005; B05D 5/08; B05C 13/00; C23C 14/042; C23C 14/50; C23C 16/042; C23C 16/458

(57) ABSTRACT

An apparatus for applying a protective coating to electronic device assemblies or other substrates may include a tray capable of holding multiple substrates. The tray can be selectively closed over the substrates. Lower and/or upper tray elements may include pre-formed masks thereon, which masks correspond to locations where protective coating materials should not adhere to the substrate. The masks may include a structural portion and a sealing portion. The structural portion may keep a substrate elevated to maintain an opening or channel through which protective coating materials may be applied to unmasked portions of the substrate. A sealing portion of the mask may engage the substrate to restrict flow of the protective coating material to the masked portion. Each tray may contain multiple substrates. A carrier may support multiple trays. Dozens and potentially hundreds of substrates may be carried by the carrier for simultaneous application of the protective coating.

### CROSS-REFERENCE TO RELATED APPLICATION

This application is a continuation of International patent application no. PCT/US2014/010739, filed on Jan. 8, 2014, and titled APPARATUSES AND SYSTEMS FOR SELECTIVELY APPLYING A PROTECTIVE COATING TO ELECTRONIC COMPONENTS AND METHODS RELATED THERETO (“the '739 PCT Application”). In the '739 PCT Application, a claim was made for the benefit of priority to U.S. Provisional Patent Application No. 61/750,342, filed on Jan. 8, 2013, and titled APPARATUSES AND SYSTEMS FOR SELECTIVELY APPLYING A PROTECTIVE COATING TO ELECTRONIC COMPONENTS AND METHODS RELATED THERETO (“the '342 Provisional Application”). The entire disclosures of the '739 PCT Application and the '342 Provisional Application are hereby incorporated by reference.

### TECHNICAL FIELD

This disclosure relates generally to apparatuses and systems for forming protective coatings. More particularly, embodiments of the present disclosure relate to apparatuses and systems for selectively forming protective (e.g., moisture-resistant, water-resistant, waterproof, etc.) coatings on portions of electronic components. More particularly still, some embodiments of the present disclosure include using a carrier for allowing multiple electronic components to collectively undergo a coating process and/or to selectively allow the protective coating on only portions of the electronic components.

### RELATED ART

With the increased development of semiconductor technology, electronic devices have played an important role in modern equipment, including mobile phones, digital cameras, computers, and the like. For example, mobile phones have become important equipment in the lives of an office worker, particularly with the advent of so-called smart phones which allow a person to not only make and receive phone calls, but also to send and receive email or other electronic messages, browse the Internet or other networks, view and create calendar events, view and edit documents, and the like. Mobile phones and other portable devices are also commonly used outside of an office setting and it is estimated that nearly 475 million smart phones were produced in 2011, and by the end of 2015 that number is expected to double and approach one billion per year.

As the portability and use of portable devices has increased, so has the likelihood that the devices will be damaged. In particular, unlike a desktop computer or other device with limited portability, a mobile device may be repeatedly subjected to different types of environments, may be dropped, or the like. For instance, when carrying a smart phone, laptop, e-reader, digital camera, tablet computing device, or other portable device, the electronic device may be exposed to moisture, such as water from rain or other environmental conditions, or the device may accidentally be dropped into a puddle, sink, toilet, or other wet location. The portable electronic device may be exposed to spilled beverages, such as water, soft drinks, tea or coffee, as people often eat and drink while working, or take their portable devices to restaurants. Although some devices may have fixed or removable covers on their respective exteriors, the covers often do not offer full protection against moisture. As a result, when the electronic device is exposed to moisture or another fluid, the fluid can leak into the device and damage electronic components within the electronic device. Some protective covers may also make a device waterproof, but such covers are often bulky and add significantly to the weight or size of the electronic device. Some users prefer the sleek appearance of the electronic device or a more compact cover, and therefore avoid using waterproof covers.

Moisture damage to an electronic device may impair its functionality or may cause the electronic device to cease operating entirely. Such devices may be expensive to replace. Indeed, in the context of mobile phones, mobile phone companies may subsidize a portion of the purchase price of the mobile phone, but only provide the subsidy once every eighteen to twenty-four months. If the device is damaged prior to the time a subsidy will be allowed, the user may have to bear the expense of replacing or repairing the device. Moreover, exposure of interior electronic components to water or other moisture can also void the warranty of the electronic device, so that a user has little choice but to expend significant sums to repair or replace the electronic device.

### SUMMARY

In one aspect, an apparatus is provided for selectively applying a protective coating to a substrate. As used herein, the term “protective coating” includes moisture resistant coatings or films, as well as other coatings or films that protect various parts of an electronic assembly from external influences. The term “moisture resistant” refers to the ability of a coating to prevent exposure of a coated element or feature to moisture. A moisture resistant coating may resist wetting or penetration by one or more types of moisture, or it may be impermeable or substantially impermeable to one or more types of moisture. A moisture resistant coating may repel one or more types of moisture. In some embodiments, a moisture resistant coating may be impermeable to, substantially impermeable to or repel water, an aqueous solution (e.g., salt solutions, acidic solutions, basic solutions, drinks, etc.) or vapors of water or other aqueous materials (e.g., humidity, fogs, mists, etc.), wetness, etc.). Use of the term “moisture resistant” to modify the term “coating” should not be considered to limit the scope of materials from which the coating protects one or more components of an electronic device. The term “moisture resistant” may also refer to the ability of a coating to restrict permeation of or repel organic liquids or vapors (e.g., organic solvents, other organic materials in liquid or vapor form, etc.), as well as a variety of other substances or conditions that might pose a threat to an electronic device or its components.

The apparatus, which is also referred to herein as a “tray,” may comprise an assembly of components that are collectively configured to engage a plurality of substrates in a manner that masks at least some desired locations on each substrate (i.e., prevents application of a protective coating material to those locations), while exposing areas of the substrate that are to be protectively coated. Such an apparatus may include two or more elements that are configured to be assembled with one another and with the substrates that are to be carried by the apparatus during a coating process. When an assembly of the apparatus and the substrates is subjected to a protective coating process, the apparatus may enable the selective application of protective coating material to the substrates.

In a specific, but non-limiting embodiment, the apparatus may comprise a closeable tray having two containment elements. One or both of the containment elements may include a mask configured to engage against the substrate and restrict or prevent an area from having the protective coating applied thereto. The mask may seal against the substrate when the tray is closed. Thereafter, when the protective coating is applied, the protective coating may flow within the tray and adhere to unmasked portions of the substrate.

A tray in accordance with some embodiments of the present disclosure may be used to selectively apply a protective coating to a substrate such as an electronic device assembly. The tray may particularly be configured to carry multiple electronic device assemblies. For instance, five, ten, twenty or even one hundred or more electronic device assemblies may be carried by a single tray.

One or both of the containment elements may have multiple masks, with each mask corresponding to a particular electronic device assembly. When an electronic device assembly is aligned with a mask, the mask can cover one or more areas where a protective coating is not wanted. The masks may be pre-formed and pre-arranged on the tray for an arrangement of the same or different electronic device assemblies. The electronic device assemblies can be positioned on one containment element, and then a second containment element may be positioned above the electronic device assemblies to close the tray. A securement device may be used to maintain the tray closed, and potentially to maintain consistent contact between a substrate and a mask. The securement device may include a clamp, mechanical fastener, some other device, or any combination thereof.

In some embodiments of the present disclosure, an electronic device assembly or other substrate may be elevated within the interior of a tray to allow the protective coating material to flow around the masks and onto unmasked surfaces. A mask itself may, for instance, have sufficient structural integrity to keep the substrate from being pressed against the interior surfaces defining an interior of the tray. When the protective coating is applied, the protective coating material can flow into openings between the substrate and the interior surfaces so as to apply to the unmasked portions of the protective coating. According to at least some embodiments of the present disclosure, the mask may include multiple portions. A structural portion may provide strength while a sealing portion may engage against the substrate. The sealing portion may have higher flexibility relative to the structural portion so as to facilitate sealing of the mask about the masked area.

A tray or other component that carries a single substrate or multiple substrates may be used in connection with other trays. For instance, a carrier may be provided to carry multiple trays. By supporting multiple trays, the carrier can simultaneously carry potentially hundreds or thousands of substrates through a protective coating station. The carrier can support a set of trays. Some or all trays may be closeable around corresponding substrates and/or with pre-formed masks that restrict application of a protective coating to some areas of the substrates. The carrier can support the trays horizontally, or the trays may be arranged vertically by the carrier. The carrier may also include wheels, rails, or other transport mechanisms to facilitate movement of the carrier, trays and substrates to, within or from a coating application station.

Methods for enclosing electronic device assemblies and other substrates within trays having preformed masks, and for applying a protective coating thereto are also disclosed.

Other aspects of the inventive subject matter of this disclosure, as well as features and advantages of various aspects of that subject matter, will become apparent to those of ordinary skill in the art through consideration of the ensuing description, the accompanying drawings, and the appended claims.

### BRIEF DESCRIPTION OF THE DRAWINGS

In the drawings:

FIG. 1 is a schematic representation of an embodiment of an apparatus for applying a protective coating to a substrate;

FIG. 2 is a schematic representation of an embodiment of an assembly line incorporating the apparatus of FIG. 1, the assembly line including a carrier for transporting substrates through all or a portion of the assembly line;

FIG. 3 is a perspective view of a cart that may be used as a carrier with the apparatus of FIG. 1 and/or the assembly line of FIG. 2 to transport substrates which are to have a protective coating applied thereto;

FIG. 4 is a side view of the cart of FIG. 3, the cart including multiple shelves carrying substrates, the shelves including masking elements to limit application of the protective coating to masked portions of the substrates;

FIG. 5 is a top view of a shelf of the cart of FIGS. 3 and 4, the shelf being opened to expose the substrates on a bottom masking element and exposing an interior of a top masking element;

FIG. 6 is a top view of the shelf of FIG. 5, the substrates being removed to expose an interior of the bottom masking element;

FIG. 7 schematically illustrates a cross-sectional view of the shelf of FIGS. 5 and 6, the shelf being closed on the substrate to mask portions of the substrate;

FIG. 8 is a perspective view of another example cart, the cart including multiple shelves for masking elements of substrates, the shelves including exterior openings facilitating application of the protective coating to the substrate surfaces;

FIG. 9 schematically illustrates another cross-sectional view of a shelf for use with a cart as described herein, the shelf including masking elements having openings therein to facilitate application of the protective coating to the substrate surfaces; and

FIG. 10 is a perspective view of another cart for use in a process or system for applying a protective coating to a portable electronic device.

### DETAILED DESCRIPTION

Apparatus and systems of the present disclosure include one or more elements for placing protective coatings on substrates. Example substrates may include, but are not limited to, electronic devices or components thereof, and coatings may be provided for adding moisture-resistance to the substrates. The extent to which a coating material is moisture-resistant may be quantified in any number of different manners, and using a variety of different metrics. For example, the ability of a coating to physically inhibit moisture from contacting a surface of a substrate may be considered to impart the coating with moisture-resistance. In other embodiments, the moisture-resistance of a coating or other material may be based on more quantifiable data. As an illustration, moisture-resistance may be measured as the rate at which water permeates through the substrate material, or by using a water vapor transfer rate. In the case of a water vapor transfer rate, the rate may be measured using any suitable technique, including known techniques. Such a measurement may measure water in units of g/m²/day or in units of g/100 in²/day (e.g., less than 2 g/100 in²/day, about 1.5 g/100 in²/day or less, about 1 g/100 in²/day or less, about 0.5 g/100 in²/day or less, about 0.25 g/100 in²/day or less, about 0.15 g/100in²/day or less, etc., through a film having a minimum thickness or an average thickness of about 1 mil (i.e., about 25.4 μm), at a temperature of 37° and at a relative humidity of 90%).

Another way in which the moisture-resistance of a coating may be determined is through use of the water contact angle when water is applied to a surface of the coating by an acceptable technique (e.g., the static sessile drop method, the dynamic sessile drop method, the dynamic Wilhelmy method, the single-fiber Wilhelmy method, the powder contact angle method, etc.). The hydrophobicity of the surface may be measured by determining the angle the base of a water droplet makes with the surface, from beneath a base of the water droplet. In an example method, the Young equation may be used. The Young equation may be stated as:

$${θ}_{c} = arccos \frac{{r}_{A} cos {θ}_{A} + {r}_{R} cos {θ}_{R}}{{r}_{A} + {r}_{A}} ,$$

where θ_{A} is the highest, or advancing, contact angle and θ_{R} is the lowest, or receding, contact angle. The values of r_{A} and r_{R} may be determined using the following equations:

$${r}_{A} = \sqrt[3]{\frac{{sin}^{3} {θ}_{A}}{2 - 3 cos {θ}_{A} + {cos}^{3} {θ}_{A}}} ;$$

$$and$$

$${r}_{R} = \sqrt[3]{\frac{{sin}^{3} {θ}_{R}}{2 - 3 cos {θ}_{R} + {cos}^{3} {θ}_{R}}}$$

A surface that has an affinity for water, and which absorbs water, is generally known as a “hydrophilic” surface. If the surface is hydrophilic, the water will spread somewhat, forming a water contact angle of less than 90° with the surface. In contrast, a hydrophobic surface, which, for purposes of this disclosure, may be considered to be water-resistant, will prevent or restrict the water or other liquid from spreading, resulting in a water contact angle of ninety degrees (90°) or greater. In general, the more the water beads on a surface, the greater the water contact angle and the greater the hydrophobicity. When water droplets bead on a surface such that the water contact angle with the surface is about one hundred twenty degrees (120°) or more, the surface may be considered to be highly hydrophobic. When the angle at which water contacts a surface exceeds one hundred fifty degrees (150°) (i.e., a water droplet on the surface is nearly spherical), the surface is said to be “superhydrophobic.” The foregoing is illustrative only, and in other embodiments other measures of water-resistance may be used. Moreover, coatings applied as discussed herein may provide other properties in addition to, or instead of, water-resistance. By way of illustration, other protective coatings may be to provide anti-static properties and/or other properties. Thus, while embodiments described herein may specifically describe examples of water-resistant protective coatings, the embodiments of the present disclosure may be equally applied to other types of protective coatings.

As discussed herein, a “substrate” may be a material, component, assembly, or other element to which a protective coating is applied. In accordance with some examples, the substrate may include one or more electronic components (e.g., semiconductor devices, printed circuit boards, electrical connectors, electrical connections (e.g., leads contacts, traces, etc.), etc.). As an example, a substrate including a single electronic component, or a combination of multiple electronic components, may be intended for use in an electronic device assembly that is itself all or a portion of an electronic device. The electronic device assembly may have one or more surfaces that could benefit from the application of a protective coating, including surfaces susceptible to damage if contacted by water or another fluid. Aspects of the present disclosure relate to apparatuses, systems and methods for applying a moisture-resistant or other protective coating to mitigate such susceptibility. In some cases, a moisture-resistant or other coating can be applied to interior components of an electronic device, whether prior to assembly or after assembly and subsequent disassembly.

For some components or assemblies, a protective coating may be applied selectively to some, but not all, portions of the corresponding substrate. For instance, an assembly may include multiple electronic components connected by one or more interfaces, ports, and the like. The protective coating could prevent or limit electrical contact between different components. Accordingly, the protective coating may not be applied where it would restrict electrical contact or other beneficial or otherwise desired connections or features. In accordance with some embodiments of the present disclosure, systems, methods and devices may be provided for selectively applying the protective coating to only desired portions of the substrate.

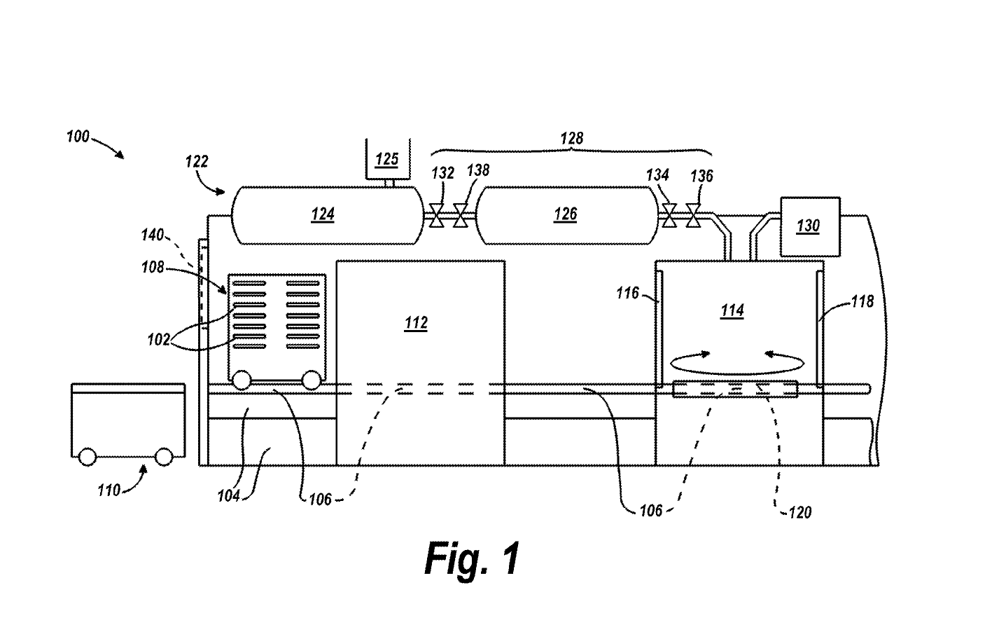

FIG. 1 illustrates an embodiment of a system 100 for selectively forming and/or applying a protective coating to one or more objects. In some embodiments, the protective coating is a moisture-resistant coating while the objects to which the coating is applied are substrates 102. In at least some embodiments, the system 100 may comprise a so-called “high throughput” apparatus, in which many substrates 102 may simultaneously have a coating applied thereto. For instance, in some embodiments dozens or even hundreds of substrates 102 (e.g., up to about one (1), five hundred (500), between five hundred (500) and one thousand (1,000), or even more than one thousand (1,000) substrates, etc.) may simultaneously have a protective coating applied thereto. In the same or other embodiments, the per-substrate coating time may also be a matter of seconds (e.g., thirty seconds or less, twenty seconds or less, ten seconds or less, five seconds or less, etc.), although in other embodiments the coating time may be greater than thirty seconds or less than five seconds.

Although not necessary for all embodiments, the system 100 may be configured to apply moisture-resistant or other protective coatings concurrently to a plurality of substrates 102. In some embodiments, and without limiting the scope of the disclosed subject matter, the system 100 may be configured to form protective coatings or films on substrates that include electronic device components. Such a substrate 102 may also be referred to herein as an electronic device assembly. The system 100 may be configured to form a protective coating or film on electronic device components as part of, or separate from, an assembly process, or even following disassembly of all or a portion of an electronic device.

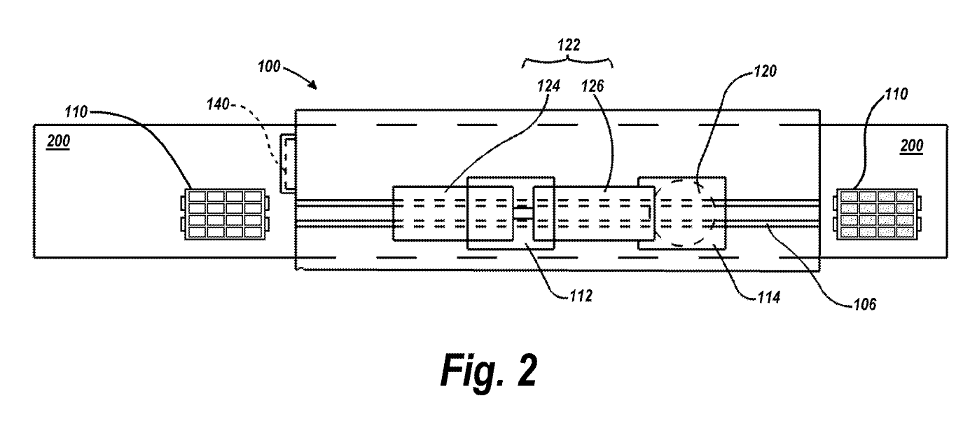

In some embodiments, such as where the substrate 102 is an electronic device assembly and the system 100 forms a moisture-resistant or other protective coating, the system 100 may include a support structure for carrying some or all of its other components. The system 100 includes, for instance, a frame 104 that may be configured for incorporation into an assembly line. An example assembly line 200 into which the system 100 may be incorporated is shown in FIG. 2, and may include any of a variety of components, such as those disclosed in U.S. patent application Ser. No. 13/736,753, filed on Jan. 8, 2013 and titled SYSTEMS FOR ASSEMBLING ELECTRONIC DEVICES WITH INTERNAL MOISTURE-RESISTANT COATINGS, the entire of disclosure of which is hereby incorporated herein.

A system 100 may include a conveyor or other system for transporting one or more substrates 102 along or through the system 100. More specifically, the illustrated embodiment includes a track 106 configured to transport a complementarily configured carrier 108, which, in turn, is configured to carry one or more substrates 102 through the system 100. In the illustrated embodiment, the track 106 is oriented along the length of the frame 104 of the system 100, and may be used to transport the carrier 108 along substantially the full length of the frame 104. While a carrier 108 may carry a single substrate 102, the carrier 108 may also carry multiple substrates. For instance, the carrier 108 may include a rack carrying multiple shelves or trays, each of which has one or more substrates 102. In such an embodiment, each shelf may have thereon a single type of substrate 102, with different shelves having the same or different types of substrates 102. In other embodiments, a shelf may have multiple different types of substrates 102.

A cart 110 may carry the carrier 108 to the track 106, and in some embodiments the cart 110 may be passed along the track 106 and/or incorporated into an assembly line (e.g., assembly line 200). When the cart 110 is used to transport the carrier 108 to the track 106, the track 106 may be positioned (e.g., at a location, at an elevation, etc.) that enables the cart 110 to be brought into a position adjacent the track 106 and to readily receive the carrier 108 from the cart 110. When used in combination, the cart 110, the track 106 and the carrier 108 may enable movement of substrates 102 throughout the system 100 as well as throughout an assembly facility, thereby enabling the system 100 to be used as part of the assembly line 200 or to be moved or used separately from the assembly line 200.

Once each substrate 102 is ready to be coated, the respective substrate 102 may be introduced into the coating station 114 of the system 100. In embodiments where the system 100 includes a track 106, the coating station 114 may be positioned along the track 106, or the track may be configured to transport the carrier 108, and potentially the entire cart 110, into and out of the coating station 114.

In some embodiments, the coating station 114 may comprise a deposition chamber. A deposition chamber may be used where, for example, the protective coating or film that is to be applied to one or more substrates 102 comprises a polymer. Example polymers that are contemplated for application using the system 100 include poly (p-xylylene), or parylene, or another material that may be formed in manner similar to parylene. U.S. patent application Ser. No. 13/849,790, filed on Mar. 25, 2013 and titled APPARATUSES, SYSTEMS AND METHODS FOR APPLYING PROTECTIVE COATINGS TO ELECTRONIC DEVICE ASSEMBLIES, the entire of disclosure of which is hereby incorporated herein, describes a non-limiting embodiment of a coating station 114 that may be used to form parylene coatings and the processes employed by that embodiment of coating station 114. Of course, a wide variety of other materials may be used as well, as may a variety of processes for depositing the materials from which a protective coating will be formed. Some non-limiting embodiments of the processes that may be employed by a coating station 114 to apply a protective coating to a substrate include, but are not limited to molecular diffusion processes, chemical vapor deposition (CVD) processes, physical vapor deposition (PVD) processes (e.g., evaporation deposition (including, but not limited to e-beam evaporation, sputtering, laser ablation, pulsed laser deposition, etc.), atomic layer deposition (ALD) processes, and physical application processes (e.g., dipping, printing, spray-on techniques, rolling, brushing, etc.) as well as any other suitable technique.

With the substrate(s) 102 in the coating station 114 and, if appropriate (e.g., in at least some embodiments where the coating station 114 comprises a deposition chamber), the doors 116 and 118 of the coating station 114 may be closed. A moisture-resistant or other protective material may then be directed from a supply system 122 into the coating station 114. The supply system 122 may, in some embodiments, be located at a higher elevation than, or even at least partially over, the track 106, the treatment chamber 112, if any, and/or the coating station 114. Such an arrangement may minimize the width of the system 100. Of course, the supply system 122 and its components may be located elsewhere on the system 100, including at one or more sides of the system 100 or assembly line 200.

In embodiments where the protective material is deposited and/or polymerizes (e.g., where the material comprises poly (p-xylylene), etc.), the materials may be supplied to a deposition chamber of the coating station 114 by introducing a precursor material (e.g., paracyclophane or an analog thereof, which is also referred to in the art as a “parylene dimer,” etc.). Prior to introduction into the deposition chamber, the precursor material may be vaporized. The vaporized precursor material may then be subjected to pyrolysis or otherwise treated to create reactive species for introduction into the deposition chamber of the coating station 114.

Embodiments of the present disclosure may further be employed in connection with the assembly of an electronic device. FIG. 2, for instance, illustrates an example assembly line 200 which includes a system 100 for applying a protective coating to substrates (e.g., electronic device assemblies or components). Although not illustrated, other components of the assembly line 200 may include components for producing the electronic device assembly, inspecting the protective coating and/or electronic device assembly, testing the electronic device assembly, and the like. As shown in FIG. 2, a cart 110 may transport substrates to the system 100. The cart 110 optionally passes along the track 106 and through the system, or otherwise provides the substrates 102 to a carrier 108 of the system 100. Upon applying the protective coating to the substrates 102, the coated substrates may exit the system 100 using a cart 110 which carries the substrates 102 along the assembly line 200.

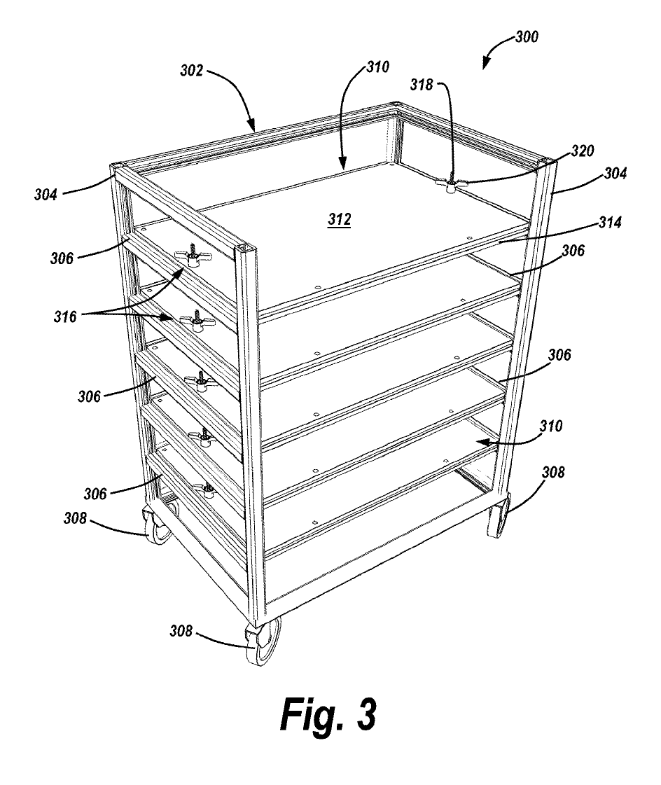

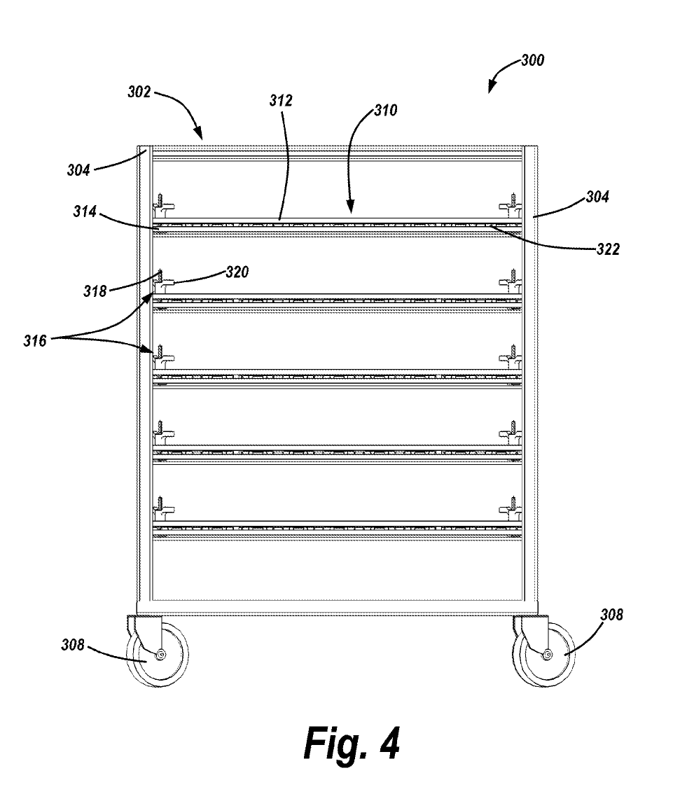

FIGS. 3 and 4 illustrate various views of an example carrier 300 which may be used to facilitate application of a protective coating to one or more substrates. For instance, the carrier 300 may be used in the system of FIGS. 1 and 2 (e.g., as the carrier 108 and/or the cart 110), although the carrier 300 may also be used in a variety of other types of systems.

As shown in FIGS. 3 and 4, the carrier 300 generally includes a support structure 302 which is in this embodiment illustrated as a frame having vertical bar supports 304 and horizontal bar supports 306. The particular components of the support structure 302 may be varied as desired, and may include additional or other structures. For instance, the support structure 302 may include a base, plates, orthogonal supports, or other supports, or some combination thereof. In some embodiments, the support structure 302 may be connected to one or more wheels 308, rollers, casters, rails, guides, or other structures that facilitate movement of the carrier 308 along a surface or within a system.

The support structure 302 of the carrier 300 is illustrated as providing support for multiple trays 310, with each tray being capable of housing one or more substrates 322. In this particular embodiment, each tray 310 is supported at least by a set of corresponding horizontal supports 306 to which the tray 310 may be attached. The tray 310 may be selectively, permanently, or partially attached in any suitable manner. By way of illustration, the tray 310 may slide within mating receiving slots in the horizontal bar supports 306. In other embodiments, the tray 310 may rest upon an upper surface of the horizontal bar supports 306 or other structures. In still other embodiments, all or a portion of the tray 310 may be welded, fastened, or otherwise attached to the support structure 302.

The trays 310 may themselves also include multiple (i.e., two or more) components. The illustrated embodiment, for instance, includes two substrate containment elements 312, 314 which are configured to maintain the substrates 322 on a corresponding tray 310. Of course, a tray, or masking assembly, may include more than two elements. In this particular embodiment, the substrate containment elements 312, 314 include a top plate (element 312) and a mating bottom plate (element 314). The illustrated top and bottom plates may be configured to sandwich one or more substrates 322 therebetween. In some embodiments, multiple substrates 322 may be sandwiched or otherwise contained between the two substrate containment elements 312, 314. As discussed in greater detail herein, openings between substrates within the containment elements 312, 314, or in other locations may allow protective coating materials to move within the trays 310 and adhere to desired surfaces of the substrates 322.

The substrate containment elements 312, 314 may be fixed at a desired position relative to each other and/or the substrates 322. In one embodiment, fixing the containment elements 312, 314 may be used to eliminate or reduce movement of the substrates 322 within the tray 310. If the substrates 322 move, they could fall out of a corresponding tray 310, bump into each other and cover surfaces where coating is desired, or otherwise produce an undesired result.

According to one example embodiment, one or more attachment devices 316 may be used to secure the substrate containment elements 312, 314 of a tray together. In this embodiment, the devices 316 are shown as clamps which include a threaded component 318 and a mating nut 320. The threaded component 318 may extend through both containment elements 312, 314 (or from one containment element 312, 314 to the other). The nut 320 may then be threaded on the threaded component 318 and tightened to secure the containment elements 312, 314 together. In this embodiment, two attachment devices 316 are shown on each tray 310. In other embodiments, however, more or fewer attachment devices 316 may be used. Moreover, other types of attachment or fastener devices may be used. By way of example, a hinge may connect the two substrate containment elements 312, 314 so that they may close around substrates 322 in a clamshell-type manner. A latch or other fastener may then be used to lock or otherwise securely maintain the tray 310 in a desired position. In other or additional embodiments, one or more clamps, clasps, screws, or other mechanical fasteners may be used. In other embodiments, indexing or positioning components (e.g., post and opening, tab and detent, etc.) may be used to position the two substrate containment elements 312, 314 relative to each other as well as to maintain them in a locked position. For instance, a post may extend through an opening and then be fastened in place using a cotter pin or other similar fastener.

The trays 310 in FIG. 3 are merely illustrative, and in other embodiments may have other forms. Moreover, the number of trays supported by a single carrier 300 may be varied as desired. Accordingly, while the carrier 300 is shown as including five trays 310, the carrier 300 could support more or fewer trays. To accommodate more or fewer trays 310, the spacing between trays 310 may be decreased or increased, the footprint size of the carrier 300 may be increased or decreased, or the like.

As discussed herein, the carrier 300 may be used in connection with a system or method in which a protective covering is applied to the substrates 322 held by the trays 310. For instance, the carrier 300 may be placed within a deposition station (e.g., station 114 of FIGS. 1 and 2). As best seen in FIG. 4, the plates or other structures forming the two substrate containment elements 312, 314 may be separated by the substrates 322 or other elements, thereby defining an opening through which the protective coating material may enter the tray 310 and flow to a position on the substrates 322. In some embodiments, all of the sides of the trays 310 may be open, whereas in other embodiments a single side, less than all sides, a portion of one or more sides, or other openings (e.g., openings 452, 454 in FIG. 9, etc.) may be provided to allow the protective coating material to flow into the tray and on to the substrates 322.

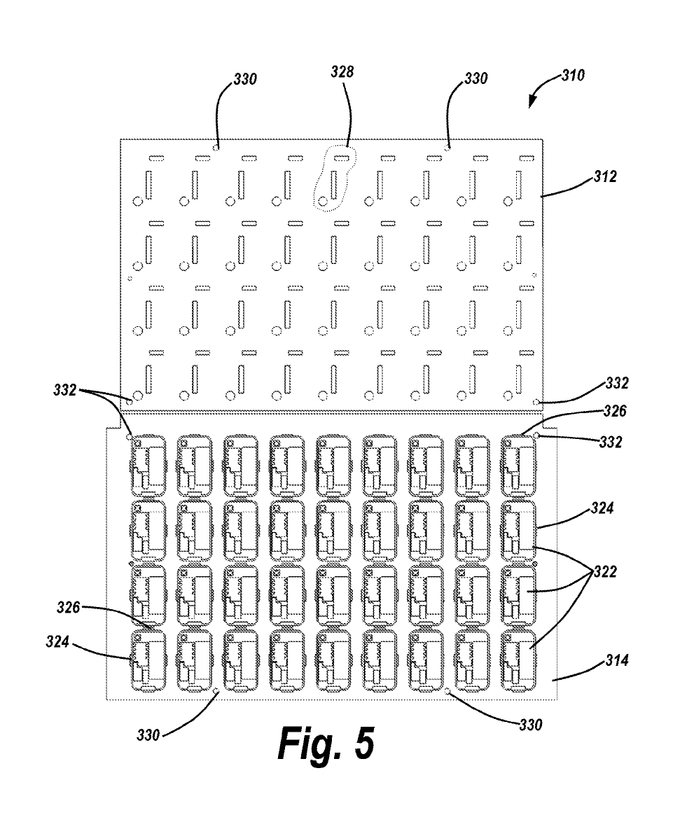

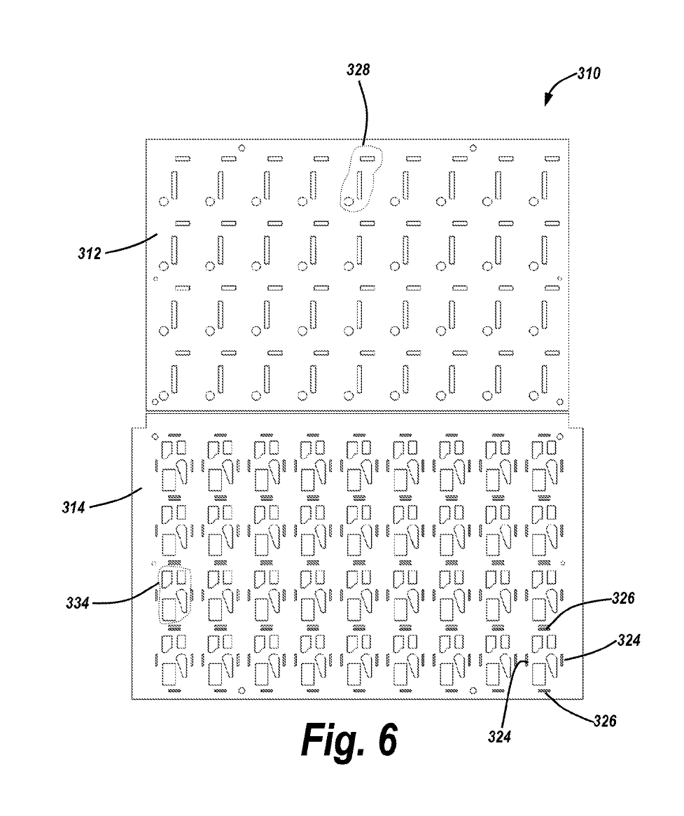

FIGS. 5 and 6 illustrate an example tray 310 in greater detail. In particular, in FIGS. 5 and 6, the clasps, clamps, or other attachment devices 316 that hold the two substrate containment elements 312, 314 together have been released so as to allow the two substrate containment elements 312, 314 to be separated. FIGS. 5 and 6 illustrate top views of the separated tray 310, and show the interior surfaces of each of the two substrate containment elements 312, 314. By rotating the upper substrate containment element 312 and placing it on the lower substrate containment element 314, the tray 310 may have a form similar to that illustrated in FIGS. 3 and 4.

FIG. 5 illustrates a particular example in which multiple substrates 322 are positioned on the lower substrate containment element 314. In this particular embodiment, the substrates 322 are arranged in a 9×4 array, although such an embodiment is merely illustrative. In other embodiments, for instance, substrates 322 may be arranged in arrays of other sizes (e.g., 4×4, 8×8, 2×5, etc.). Moreover, the substrates 322 may alternatively be arranged in other patterns rather than as arrays of columns and/or rows.

To facilitate the arrangement of the substrates 322, the lower substrate containment element 314 includes multiple indexing elements 324, 326. In particular, the illustrated substrates 322 are generally rectangular in shape and the indexing elements 324, 326 define a generally rectangular opening therebetween sized to accommodate one substrate 322. In particular, the indexing elements 324 are shown as lateral indexing elements while the indexing elements 326 are upper and lower indexing elements. The indexing elements 324, 326 may collectively act as an alignment tool that defines the particular location for each substrate 322 of the tray 310. The indexing elements 324, 326 are merely optional, but may be used in some embodiments. An example embodiment in which indexing elements 324, 326 may be used is in connection with masking portions of the substrate 322.

Masking the substrate 322 may generally be used to prevent or restrict a coating (e.g., a moisture-resistant coating) from being applied to surfaces where its application is not desired. For instance, two electronic components may communicate over an electrical connection. A coating may cover contacts used in enabling the electrical connection, and may therefore prevent the components from properly communicating with one another. By masking, or covering, the contacts during the coating application process, the electrical contacts may be prevented from having a coating sufficient to interrupt electrical connection. Of course, a coating may also not be desired in other embodiments. For instance, a camera or display may be a part of a substrate 322. If the coating is opaque, a camera lens, flash, display, or other component may be masked so that the coating is not applied to all or a portion thereof.

The tray 310 may be configured to apply a mask to one or more portions of the substrates 322 when the substrate containment elements 312, 314 are mated. In FIG. 5, for instance, the upper substrate containment element 312 is shown as including multiple masks for each substrate, the multiple masks being collectively identified as the mask 328. Each portion of the mask 328 may correspond to a location of a substrate 322 where it may be necessary or beneficial to prevent or limit application of a protective coating. When the upper substrate containment element 314 is placed on the lower substrate element 312 and connected thereto, the masks 328 may be aligned with the corresponding locations of the substrate 322 where the coating is not wanted. To facilitate alignment of the masks 328 with the substrates 322, there may also be one or more additional indexing elements. In this particular embodiment, indexing elements 330, 332 are provided to index the position of the upper substrate containment element 312 relative to the lower substrate containment element 314. Other embodiments may, however, include additional or other indexing elements (e.g., indexing elements on the upper substrate containment element 312 for indexing relative to some or all substrates 322).

The upper substrate containment element 312 and the masks 328 thereon may be used to mask and ultimately protect portions of an upper surface of the substrates 322 from having a protective coating applied thereto. It may, however, be beneficial to mask more than a single surface of the substrate 322. For instance, a lower surface of the substrate 322 may also have the protective coating applied thereto. In such an embodiment, if portions of the lower surface are to be masked, the lower substrate containment element 314 may also include one or more masking elements.

FIG. 6 illustrates an example of the tray 310 of FIG. 5, but with the substrates 322 removed so as to illustrate the interior surface of the lower substrate containment element 314. As shown in FIG. 6, the lower substrate containment element 314 may also include a set of components configured to contact the substrates 322 and prevent or restrict the application of a protective coating thereto. In this particular embodiment, four masking elements (collectively designated as the mask 334) may be applied to the lower surface of each substrate 322 once the corresponding substrate 322 is positioned on the lower substrate containment element 314. Moreover, this particular embodiment illustrates the use of indexing elements 324, 326 in conjunction with the mask 334. In such an embodiment, once a substrate 322 is positioned on the lower substrate containment element 314 as facilitated by the indexing elements 324, 326, the corresponding mask 334 may engage the corresponding locations of the substrate 322 in preparation for application of the protective coating.

While FIGS. 5 and 6 illustrate the use of upper and lower substrate containment elements 312, 314, as well as multiple masks 328, 334, it should be appreciated that such an embodiment is merely illustrative. For instance, in some embodiments, one or more portions of only a single surface of the substrates 322 may be masked. In such an embodiment, it may be useful to only provide the lower substrate containment element 314, so as to allow the full upper surface of the substrate 322 to have the protective coating applied thereto.

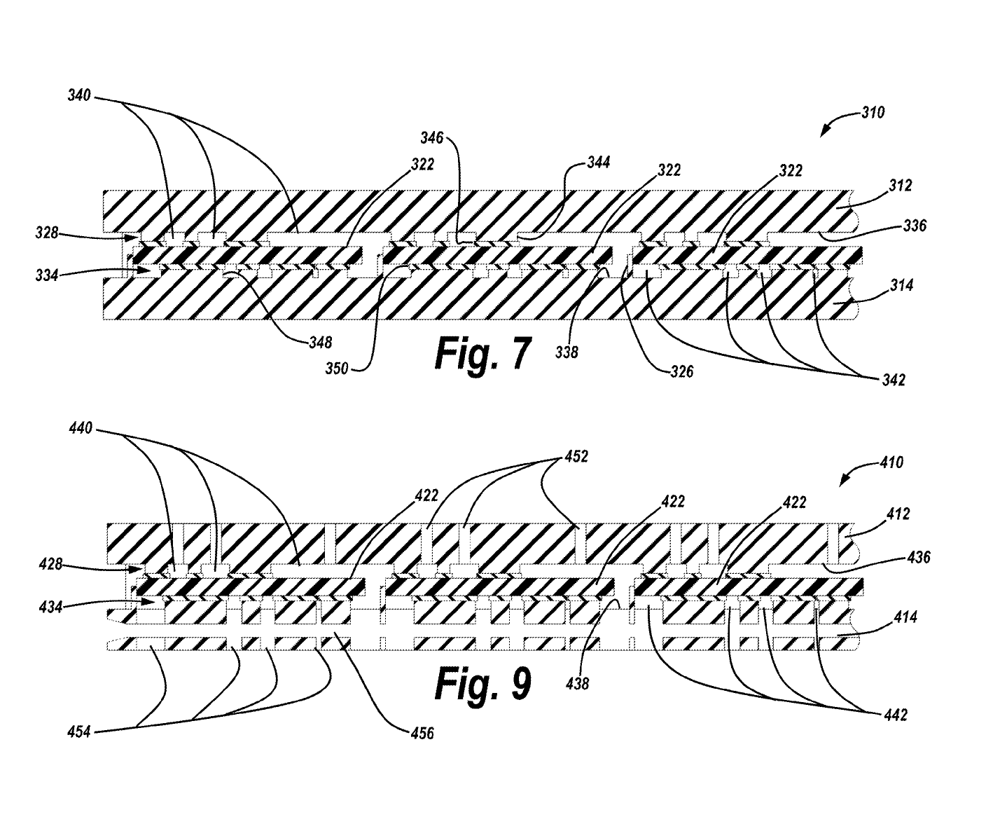

FIG. 7 schematically illustrates a cross-sectional view of an embodiment of the tray 310, when substrates 322 are positioned between upper and lower substrate containment elements 312, 314. In this particular embodiment, each of the upper and lower substrate containment elements 312, 314 also includes a corresponding mask 328, 334. As discussed herein, the masks 328, 334 may be used to cover portions of the substrates 322 to prevent or restrict the application of a protective coating to the covered portion. In the embodiment illustrated in FIG. 7, each mask 328, 334 is shown as having multiple segments, with each corresponding to an area of the substrate 322 that can be protected during the application of a protective coating. In other embodiments, however, a mask may have a single segment for covering only a single area of the substrate 322.

According to some embodiments of the present disclosure, substrates 322 are offset relative to the interior surfaces 328,334 of the corresponding plates or other structures defining the upper and lower substrate containment elements 312, 314. As shown in FIG. 7, for instance, the masks 334, 338 may extend from the interior surfaces 336, 338 and support the substrates 322 which are held apart from the interior surfaces 336, 338. By maintaining the substrates 322 off of the interior surfaces 336, 338, portions of the upper and lower surfaces of the substrates 322 remain exposed, thereby allowing the protective coating to be applied thereto while the tray 310 is in a deposition chamber or other device or system used to apply a protective coating to the substrates 322.

In the particular example shown in FIG. 7, the upper mask 328 includes three masking segments with an opening 340 between the various masking segments and adjacent masks 328. The opening 340 may include a series of one or more channels through which the protective coating material may flow to be applied to the upper surface of the substrates 322. Similarly, in the example in FIG. 7, the lower mask 334 includes four masking segments with an opening 342 between the various masking segments and the adjacent masks 334. Protective coating material may flow or diffuse through the one or more channels of the opening 342 for application to the lower surface of the substrates 322.

The protective coating material may flow into the openings 340, 342 in any suitable manner. For instance, as shown in FIG. 7, there may be a separation between the upper and lower substrate containment elements 312, 314. Such a separation may exist along a single edge or along multiple—and possibly all—edges of the tray 310. By separating the upper and lower substrate containment elements 312, 314, protective coating material may flow between the upper and lower substrate containment elements 312, 314 and into the openings 340, 342. In other embodiments, however, material may be provided in other manners, including through injection, through openings in the exterior surfaces of the upper and lower substrate containment elements 312, 314, or in other manners, or some combination thereof.

To allow the protective coating material to pass through the openings 340, 342, or other channels and adhere to the surfaces of the substrate 322, some embodiments contemplate the masks 328, 334 having sufficient structural integrity to avoid collapsing of the openings 340, 342. The openings 340, 342 could collapse where, for instance, the masks 328, 334 are flexible and the weight of the substrate 322 and/or upper substrate containment element 312 is sufficient to significantly compress the masks 328, 334. Additionally, or alternatively, the masks 328, 334 could collapse where the upper and lower substrate containment elements 312, 314 are secured together with sufficient pressure (e.g., through the use of clamp 316 of FIGS. 3, 4).

Some embodiments of the present disclosure may include means for maintaining the openings 340, 342 open for the application of a protective coating. FIG. 7, for instance, illustrates the masks 328, 334 as including multiple portions. In this particular embodiment, for instance, the masks 328 is shown as including a structural portion 344 and a sealing portion 346. The structural portion 344 may connect to the interior surface 336 of the upper substrate containment element 312 and be sufficiently rigid to provide structural integrity for maintaining the openings 340 open (e.g., by preventing or restricting the substrate 322 from coming into contact with the interior surface 336). The structural portion 344 may be formed of any number of suitable materials, may be integrally formed with the upper substrate containment element 312, or may be formed separate therefrom and then attached thereto using a fastener, adhesive, welding, thermal bonding, or other mechanism, or some combination thereof. Accordingly, the structural portion 344 of the mask 328 may be formed of the same material as the upper or lower substrate containment elements 312, 314, or of an entirely different material.

According to some embodiments, the sealing portion 346 may be more flexible relative to the structural portion 344. For instance, the flexible material may be formed of a rubber, silicone, plastic, or other material intended to at least partially flex or compress when engaged against the substrate 322. By flexing or compressing, the sealing portion 346 may create a seal around a contact, connector, or other portion of the substrate 322, thereby sealing against the protective coating material being applied thereto.

FIG. 7 further illustrates the lower mask 334 of the lower substrate containment element 314 as being similar to the upper mask 328. Thus, the illustrated lower mask 334 also includes multiple portions, including a structural portion 348 and a sealing portion 350. The lower mask 334 and upper mask 328 may therefore be similarly constructed, although in other embodiments they may have different constructions, materials, purposes, and the like.

The relative sizes of the various portions of the masks 328, 334 may vary as desired for a particular application. For instance, where a relatively high pressure is to be applied to secure the upper and lower substrate containment elements 312, 314 together, the structural portions 344, 348 can have an increased height as compared to an application where a lower pressure is to be used. Alternatively, the sealing portions 346, 350 can be of different thicknesses. Of course, the material properties of the structural portions 344, 348 may affect their respective sizes. In accordance with some embodiments, for instance, the height of a mask (e.g., mask 328 or mask 334) may be between 1 mm and 20 mm. The heights of the mask and its structural portions 344, 348 and its sealing portions 346, 350 may be configured (e.g., thin enough, etc.) to avoid any undesirable effect on the efficiency with which a protective coating is deposited onto a substrate. In such embodiments, the height of the structural portions 344, 348 may be about half the overall height of the corresponding mask. In other embodiments, however, the height of the structural portion may be less than the height of a corresponding sealing portion. In still other embodiments, the structural portion may have a height greater than a height of the sealing portion. In still other embodiments, more than two elements may be provided, or a single element may be provided as part of a mask. For instance, a material sufficiently flexible to create desired seal may form the full mask and have sufficient height to maintain the openings 340, 342 so that protective coating material can flow therethrough.

As discussed herein, protective coatings may be applied to substrates in a number of different manners, and using a number of different systems or components. For instance, in FIGS. 1 and 2, a protective coating may be applied using a coating station. The coating station optionally rotates while protective coating materials are dispersed within a chamber of the coating station. Multiple substrates may simultaneously have the protective coating materials applied thereto, and the multiple substrates may include a tray. The tray may be open, although as discussed with respect to FIGS. 3-7, the tray may also be closed over the substrates (e.g., by sandwiching the substrates between plates, using a clamshell enclosure, etc.).

In embodiments in which the tray is closed around substrates, a mechanism may be provided for allowing protective coating material to enter the tray and adhere to the substrates. In FIGS. 3-7, for instance, the trays may be open along one or more peripheral edges thereof. Protective coating material may pass into the tray and be deposited on, or otherwise attach to, the substrates. Optionally, rotating the tray (or carts of multiple trays), and possibly changing a direction of rotation, may allow the protective coating material to be deposited in a more uniform manner.

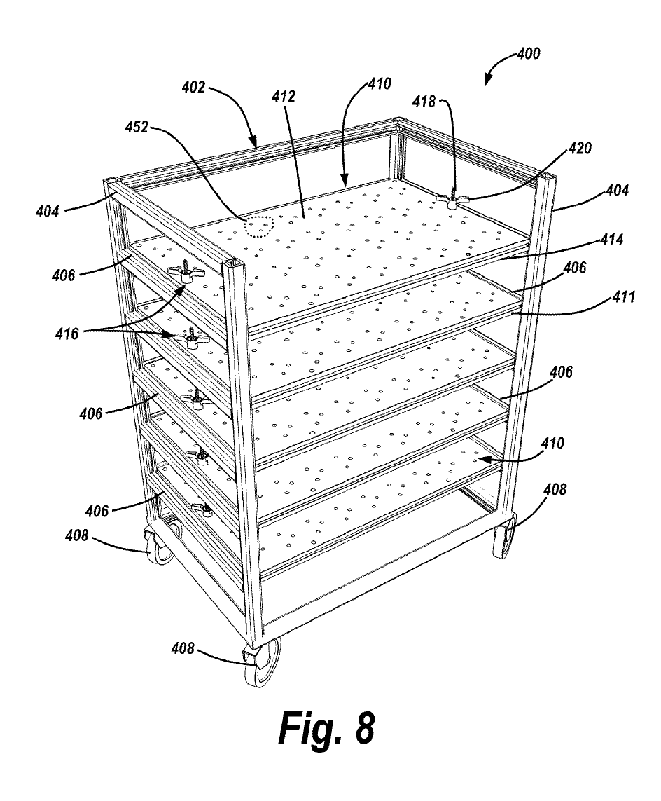

In embodiments in which substrates are at least partially enclosed in a tray, protective coating material may be provided in other or additional manners for application to the substrates. For instance, FIG. 8 illustrates an example carrier 400 for use in applying a protective coating to various substrates. The carrier 400 may be similar to the carrier 300 of FIGS. 3 and 4, and can include a support structure 402 having vertical supports 404 and horizontal supports 406 defining a frame. In some embodiments, the support structure 402 may be connected to one or more wheels 408, rollers, casters, rails, guides, or other structures that facilitate movement of the carrier 408 along a surface or within a system.

The support structure 402 of the carrier 400 may provide support for multiple trays 410, with each tray 410 being capable of enclosing one or more substrates. In this particular embodiment, each tray 410 is supported at least by a set of corresponding horizontal supports 406 to which the tray 410 may be attached. The trays 410 may themselves also include multiple components. The illustrated trays 410, for instance, include two substrate containment elements 412, 414 which are configured to cover at least two surfaces of the substrates on the tray 410. In this particular embodiment, the substrate containment elements 412, 414 include an upper plate (element 412) and a corresponding lower plate (element 414). The illustrated upper and lower plates may be configured to sandwich one or more substrates therebetween. Optionally, one or more edges (e.g., the illustrated front edge 411) may remain open to allow protective coating material to enter the tray 410. In some embodiments, however, more openings or other locations may be provided for inserting the protective coating material into the trays 410.

More particularly, FIG. 8 illustrates the trays 410 as including the upper substrate containment element 414 with sets 452 of one or more openings. The openings of the sets 452 may pass through a full width of the element 412. Consequently, when the trays 410 are placed within a coating station or similar system, the protective coating material can pass through the upper element 412 and into an interior space of the tray 410. The substrates within the interior space may then be coated with the protective coating material.

FIG. 9 schematically illustrates a cross-sectional view of one embodiment of a tray 410 from the carrier 400 of FIG. 8. As shown in FIG. 9, the tray 410 may include upper and lower substrate containment elements 412, 414 with substrates 422 sandwiched therebetween. The upper and lower substrate containment elements 412, 414 may have corresponding interior surfaces 436, 438 which are offset. An interior of the tray 410 may be the space between the interior surfaces 436, 438.

The substrates 422 of FIG. 9 are located within the interior of the tray 410, and are supported by masks 428, 434. The masks 428, 434 may be similar to masks 328, 334 of FIG. 7, and thus optionally include multiple portions, such as a structural portion and a sealing portion, as described herein. The masks 428, 434 maintain the substrates 422 off of the interior surfaces 436, 438. As a result, the interior of the tray 410 includes openings 440, 442 on opposing sides of the substrates 422. The protective coating material can accumulate within the openings 440, 442 and apply to the substrates 422. The protective coating material may pass into the openings 440, 442 through any suitable mechanism, including through peripheral edges as described with respect to FIG. 7. As shown in FIG. 8, however, there may also be sets 452 of openings in the upper substrate containment element 412. Protective material may enter the tray 410 through the sets 452 of openings and pass into the interior of the tray 410.

Any number of openings may be provided within the sets 452. For instance, the illustrated embodiment includes three openings in each set 452. In other embodiments, however, there may be a single opening, two openings, or more than three openings. According to some embodiments, the number of openings may generally correspond to the number of mask portions. In FIG. 9, for instance, there are three portions of the mask 428 and three openings, with each opening corresponding to a location of the opening 440 between mask portions. Such an embodiment is, however, merely illustrative and different numbers of openings, masking portions, and the like may be provided. Indeed, the set 452 may include a single hole or opening to access the interior of the tray 410, even where the mask 428 has multiple portions, or there may be more openings than mask portions.

Other mechanisms for insertion of the protective coating material may also be provided. In FIG. 9, for instance, the lower substrate containment element 414 is also shown as including openings 454 extending therethrough. Protective coating material may also pass into the interior of the tray 410 through the openings 454 which open at the interior and exterior surfaces of the lower substrate containment element 414. In some embodiments, however, access to the tray 410 may extend through lateral openings into the tray 410. A lateral channel 456 is also shown in FIG. 9. Protective coating material may flow into channel 456 through a deposition, injection or other process, and then extend into the opening 442 for application to the unmasked portions of the substrates 422. The use of lateral channels and/or through holes may create a network of openings, which in some embodiments can allow the protective coating material to more quickly be applied to the substrates, to more uniformly apply to the substrates, or to otherwise be applied in a desirable manner.

To further facilitate application of the protective coating, some embodiments contemplate a uniform insertion of protective coating material into the tray 410. In particular, FIG. 9 illustrates the sets 452, 454 of openings as being positioned at different spacings, and corresponding to locations between portions of the masks 428, 434. In other embodiments, however, the openings may be more uniform. Each of the through-holes or other openings may instead be of a uniform size and/or equally spaced apart. Protective coating material may then flow about evenly into each opening. The portions of the masks 428, 434 that demarcate locations where the coating should not be applied, may cover the interior portion of the holes, thereby blocking entry of the protective material into a marked-off portion. Other holes that are not blocked by the masks 428, 434 may continue to allow protective coating material to flow through the tray 410.

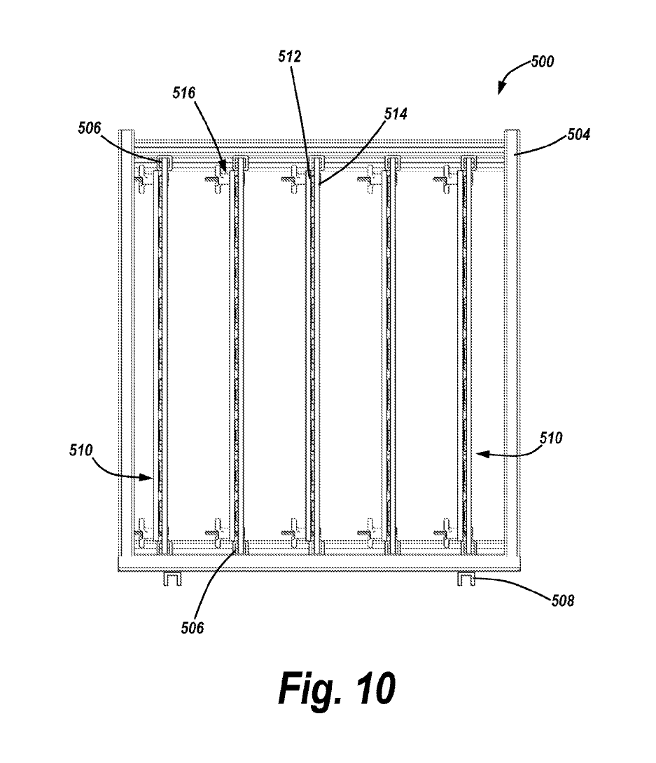

Trays 310 and 410 of FIGS. 3-9 illustrate example embodiments in which the substrates are held in a horizontal position while a protective coating is applied thereto. In other embodiments, however, substrates may be maintained in other orientations. FIG. 10, for instance, illustrates an example embodiment in which a carrier 500 includes a support structure 502 for maintaining a set of trays 510 in a vertical orientation. In this particular embodiment, the support structure 502 includes vertical supports 504 connected to a set of lateral supports 506. A set of one or more guides 508 may also be provided. The guides 508 may be configured to correspond with a rail or other transport system of a protective coating application device, thereby allowing the carrier to move between different stations of the device, or within a single station.

The lateral supports 506 are shown as being spaced apart between the vertical supports 504, with each lateral support 506 being configured to support a single tray 510. The trays 510 are illustrated as being configured to substantially enclose substrates, and include first and second substrate enclosure elements 512, 514. To support the trays, the lateral supports 506 include a slot into which a portion of the second enclosure elements 514 may be inserted. One or more securement elements, such as clamps 516, may also be used to secure the first and second substrate enclosure elements 512, 514 together while in the illustrated vertical orientation.

Within the trays 510, one or more components may be provided to maintain the substrates 522 in position, so they do not slip or fall to the bottom of the tray 510. As described previously, trays of a carrier may include indexing elements to facilitate proper positioning of a substrate. Such indexing elements may optionally act as positioning elements to keep the substrates in the desired position. In the same or other embodiments, compressive forces may keep the substrates in position. Masking elements may, for instance, be included in the trays 510. As discussed herein, masking elements may have flexible sealing portions. When the clamps 516 are applied, the sealing portions of a mask may frictionally secure the substrates in the desired position.

Embodiments used herein may be used to apply protective coatings for any number of different purposes. For instance, substrates may include electronic devices or electronic device components. Such devices and components may be damaged if exposed to moisture or dust, are dropped, or otherwise subjected to undesirable conditions. The protective coating applied to substrates using the carriers, trays and other embodiments disclosed herein may therefore provide protection against moisture or dust, provide cushioning against impacts, or other features, or any combination thereof. Moreover, such protective coatings may be desired for use with a number of different types of devices. Accordingly, a carrier, tray or other device may be configured for use with multiple different devices or other substrates. As an example, a carrier may include multiple trays. All trays may be used for a single type of device or other substrate. In other embodiments, each tray may be used for a particular type of device or other substrate, and multiple trays of different types may be used in the same carrier. In still other embodiments, a single tray may be used for multiple different types of substrates. According to some embodiments, corresponding trays are swappable. More particularly, each of different types of trays may be used interchangeably with a carrier, thereby allowing a single carrier to be universally used in myriad applications.

Trays and other apparatus that may carry electronic components or other substrates may be pre-formed and/or customizable for use with devices, systems and methods of the present disclosure. In some embodiments, a tray may have a bottom plate with an array of pre-formed masks, each mask being for the same type of substrate. A corresponding top plate or lid may similarly be formed to mate with the bottom plate, and optionally includes a pre-formed mask of its own. Of course, indexing elements may be provided on the top or bottom plate to facilitate alignment of the substrates relative to the masks.

Although the foregoing disclosure provides many specifics, these should not be construed as limiting the scope any of the ensuing claims. Other embodiments may be devised which do not depart from the scopes of the claims. Features from different embodiments may be employed in combination. Accordingly, all additions, deletions and modifications to the disclosed subject matter that fall within the scopes of the claims are to be embraced thereby. The scope of each claim is indicated and limited only by its plain language and the full scope of available legal equivalents to its elements.

1. A tray for applying a protective coating to a plurality of substrates, comprising:
an enclosure, the enclosure including mating first and second containment elements and an interior therebetween;
at least one mask connected to the enclosure, the at least one mask for substantially sealing against a portion of a substrate positioned in the interior of the enclosure between the first and second containment elements and within the interior;
a securement element for selectively securing the enclosure in a closed position; and
one or more openings through which protective coating materials may enter the enclosure and be applied to the substrate.

2. The tray of claim 1, wherein the at least one mask includes a structural portion.

3. The tray of claim 1, wherein the at least one mask includes a sealing portion.

4. (canceled)

5. The tray of claim 1, wherein the at least one mask includes a first mask on the first containment element and a second mask the second containment element.

6. The tray of claim 1, wherein the at least one mask includes a plurality of masks the first containment element.

7. (canceled)

8. The tray of claim 1, further comprising one or more indexing elements on the enclosure.

9. The tray of claim 8, wherein the one or more indexing elements are configured to facilitate alignment of:
one or more substrates relative to the enclosure; and/or
the first and second containment elements relative to each other.

10-12. (canceled)

13. The tray of claim 1, wherein the at least one mask includes a plurality of masks configured to correspond to a plurality of substrates.

14. A carrier for use in transporting a plurality of substrates within a protective coating application system, the carrier comprising:
at least one tray, wherein the at least one tray is selectively positionable between an open configuration and a closed configuration, and wherein the at least one tray includes a plurality of masking elements for simultaneously masking one or more substrates positionable within the at least one tray when in the closed configuration; and
a support structure for supporting the at least one tray while in at least the closed configuration.

15. The carrier recited in claim 14, further comprising:
a transport mechanism for facilitating transport of the carrier through a protective coating application system.

16. (canceled)

17. The carrier recited in claim 14, wherein the plurality of masking elements include a first mask for masking a first surface of a substrate and a second mask for masking a second surface of the substrate, the second surface opposing the first surface.

18. (canceled)

19. The carrier recited in claim 14, wherein the plurality of masking elements include a plurality of masks for masking same sides of a plurality of substrates.

20. The carrier recited in claim 19, wherein substrates of the plurality of substrates are substantially identical to one another.

21. The carrier recited in claim 19, wherein at least one of the plurality of masking elements includes multiple, discrete masking segments for a substrate.

22. The carrier recited in claim 14, comprising a plurality of trays.

23. (canceled)

24. The carrier recited in claim 22, wherein the multiple trays are configured to collectively carry between one hundred and one thousand two hundred substrates.

25. The carrier recited in claim 14, wherein the tray is configured to simultaneously carry, and the plurality of masking elements are configured to correspond to, between ten and one hundred substrates.

26. The carrier recited in claim 14, wherein the support structure supports the at least one tray in a horizontal orientation or in a vertical orientation.

27. The carrier recited in claim 14, wherein the plurality of masking elements include:
a support portion for maintaining open a passageway for flow of protective coating material; and
a sealing portion for engaging against a corresponding substrate and substantially sealing off a portion against application of the protective coating material.

28. A method for applying a protective coating to multiple substrates, comprising:
accessing a tray having a plurality of masks, each of the plurality of masks being configured to align with a corresponding substrate;
placing a plurality of substrates on the tray while the tray is in an open orientation;
closing the tray about the plurality of substrates;
providing the closed tray to a protective coating station for application of a protective coating to the plurality of substrates;
opening the closed tray following application of the protective coating to the plurality of substrates; and
removing the plurality of substrates from the tray, wherein the removed plurality of substrates have a protective coating applied thereto, the protective coating being substantially absent at locations corresponding to the plurality of masks.

29-44. (canceled)
